(19) United States
(12) Patent Application Publication
(10) Pub. No.: US 2005/0156324 A1
(43) Pub. Date: Jul. 21, 2005

(54) Method for manufacturing connection construction

(75) Inventors: Yoshimi Nakase, Anjo-city (JP); Yoshitaugu Sakamoto, Toyohashi-city (JP); Hiroshi Ohki, Toki-city (JP); Tomomasa Yoshida, Aichi-gun (JP); Norio Kano, Okazaki-city (JP)

Correspondence Address: POSZ LAW GROUP, PLC, 12040 SOUTH LAKES DRIVE, SUITE 101, RESTON, VA, 20191, US

(73) Assignee: DENSO CORPORATION & TOYOTA JIDOSHA KABUSHIKI KAISHA

(21) Appl. No.: 11/036,135

(22) Filed: Jan. 18, 2005

(30) Foreign Application Priority Data
Jan. 20, 2004 (JP) 2004-11745

(51) Int. Cl. H01L 23/48; H01L 23/52

(52) U.S. Cl. 257/778

(57) ABSTRACT

A method for manufacturing a connection construction having a first and a second connection members bonded therebetween with a solder layer includes the steps of: sandwiching the solder layer between the first and the second connection members; decompressing the solder layer down to a first pressure with maintaining a first temperature, which is lower than a solidus of the solder; heating the solder layer up to a second temperature with maintaining the first pressure, the second temperature being higher than a luquidus of the solder; compressing the solder layer up to a second pressure with maintaining the second temperature, the second pressure being higher than the first pressure; and hardening the solder with maintaining the second pressure.

### CROSS REFERENCE TO RELATED APPLICATION

This application is based on Japanese Patent Application No. 2004-11745 filed on Jan. 20, 2004, the disclosure of which is incorporated herein by reference.

### FIELD OF THE INVENTION

The present invention relates to a method for manufacturing a connection construction having a first and a second connection members bonded with a solder layer.

### BACKGROUND OF THE INVENTION

A connection construction having the first and the second connection members bonding with a solder layer therebetween in a prior art is such that, for example, a semiconductor device as the first connection member is bonded on a substrate or a lead frame as the second connection member with a solder layer. This solder bonding process is performed in such a manner that a solder pellet is sandwiched between the semiconductor device and the substrate or the lead frame, and then, they are heated in a continuous hydrogen reflow furnace in an atmosphere.

In the solder bonding process, a void may be generated in the solder layer. This void is mainly generated in the solder layer by winding air around the atmosphere when the melted solder pellet material spreads to a predetermined region at the time or after the pellet as a solder melts. In a case where the void is disposed in the solder layer, a heat radiation path between the first and the second connection members is blocked by the void. Therefore, the heat radiation performance is reduced. Further, the bonding strength of the solder layer is reduced.

In the prior art, to reduce the void in the solder layer, the surface area of a solder pellet is decreased so that a shape of the solder layer is designed appropriately. Further, the process time for melting the solder becomes longer so that a temperature profile in the solder bonding process is determined appropriately. Specifically, in Japanese Patent Application Publications No. H05-283570 and H06-69387, the solder bonding process is performed in a depressurized atmosphere in a case where a large size power device is bonded to the substrate with a solder layer. Here, the power device is suitably used for a power module to control a large electric power. This is because the power device is required to have the sufficient heat radiation performance. In this case, the first and the second connection members sandwich the solder layer, and then, the solder layer is melted. After that, the atmosphere is decompressed by a vacuum system so that the void in the solder layer is removed. Thus, the number of the void in the solder layer is reduced.

However, the above method has following problems. For example, when the void in the solder layer in the large size power device is removed in a defoaming process, a comparatively low pressure is necessitated to remove the void since the area of the solder layer becomes larger. Therefore, the vacuum system having high evacuation performance is necessitated, and further, it is required to evacuate for a long time. Thus, a manufacturing cost is increased. Further, recently, the solder does not include lead (i.e., Pb) substantially, so that the above requirements are more serious, compared with the solder including lead.

Specifically, the solder without lead (i.e., Pb-free solder) has large surface tension larger than the conventional solder including lead. Therefore, the Pb-free solder has low solder wettability for expanding to the connection member so that the Pb-free solder does not expand widely. Accordingly, when the Pb-free solder is melted and expanded, the atmospheric gas may be introduced in the melted Pb-free solder easily. Further, the void is not removed easily. Therefore, the void is generated in the solder layer easily.

### SUMMARY OF THE INVENTION

In view of the above-described problem, it is an object of the present invention to provide a new method for manufacturing a connection construction having the first and the second connection members bonded with a solder layer.

A method for manufacturing a connection construction having a first and a second connection members bonded therebetween with a solder layer made of a solder is provided. The method includes the steps of: sandwiching the solder layer between the first and the second connection members; decompressing the first and the second connection members with the solder layer down to a first pressure with maintaining a first temperature, which is lower than a solidus of the solder; heating the first and the second connection members with the solder layer up to a second temperature with maintaining the first pressure, the second temperature being higher than a luquidus of the solder; compressing the first and the second connection members with the solder layer up to a second pressure with maintaining the second temperature, the second pressure being higher than the first pressure; and solidifying the solder with maintaining the second pressure.

In the above method, even when the melted solder pellet involves the atmospheric gas so that the void is formed, the void is collapsed by the second pressure. This is because the inner pressure of the void is the first pressure, and then, the atmospheric pressure becomes the second pressure, which is higher than the first pressure, so that the void is collapsed. Thus, the void becomes much smaller or is disappeared so that the void in the melted solder pellet is reduced. Thus, the present decompressed defoaming method does not require the vacuum system having high evacuation performance as decompressing means for decompressing the connection construction. Further, the decompressing process time for decompressing the construction becomes shorter; and therefore, the void in the solder layer is effectively reduced with a low cost.

Preferably, the method further includes the step of: preliminarily heating the first and the second connection members with the solder layer up to a preliminarily heating temperature with maintaining an atmospheric pressure before the step of decompressing, the preliminarily heating temperature being equal to or lower than the solidus of the solder. Further, it is preferred that the solder is made of lead free solder.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional view showing a connection construction according to a preferred embodiment of the present invention;

FIG. 2 is a cross sectional view showing the construction before soldering, according to the preferred embodiment;

FIG. 3 is a graph showing a relationship between a void area ratio and a pressure in a decompressed process, according to the preferred embodiment;

FIG. 4A is a graph showing a temperature profile and a pressure profile in a process of a comparison decompressed defoaming method, and FIGS. 4B to 4D are cross sectional views showing the construction in each steps, according to the preferred embodiment; and

FIG. 5A is a graph showing a temperature profile and a pressure profile in a process of a decompressed defoaming method, and FIGS. 5B to 5D are cross sectional views showing the construction in each steps, according to the preferred embodiment.

### DETAILED DESCRIPTION OF THE PREFERRED EMBODIMENT

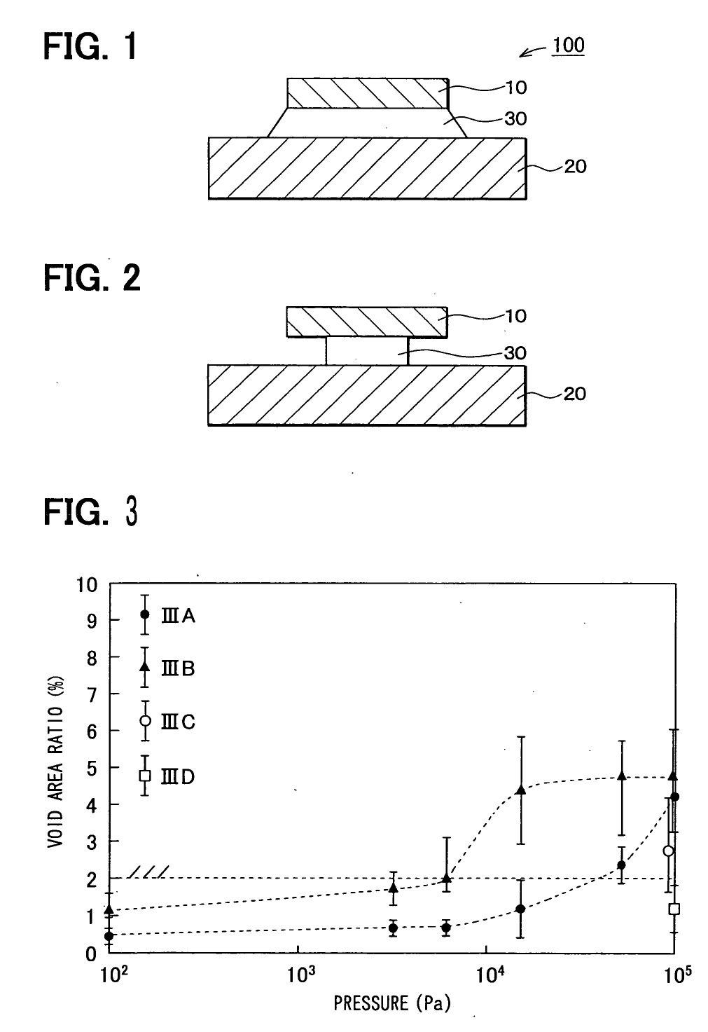

A connection construction 100 according to a preferred embodiment of the present invention is shown in FIG. 1. The connection construction 100 includes an IGBT device 10 (insulated gate bipolar transistor) as the first connection member and a ceramic substrate 20 as the second connection member, which are bonded with a solder layer 30. The IGBT device 10 is a conventional silicon semiconductor chip including the IGBT manufactured by a conventional semiconductor process. The ceramic substrate 20 made of aluminum includes a wire and the like.

Here, a nickel electrode is formed on the IGBT device at a connection portion between the IGBT and the solder layer 30, and further another nickel electrode is formed on the ceramic substrate 20 at another connection portion between the substrate 20 and the solder layer 30. The nickel electrode is formed of a nickel plating method. Thus, the nickel electrode and the solder layer 30 are bonded directly so that the solder layer can connect to the substrate 20 or the IGBT device strongly. Thus, the solder bonding strength therebetween is secured.

The solder layer 30 is made of Pb-free solder with including no lead substantially. For example, the Pb-free solder is composed of a few weight percent of antimony (i.e., Sb) and remaining percent of tin (i.e., Sn). Although the first and the second connection members 10, 20 are the power device such as the IGBT device and the ceramic substrate, the first and the second connection members can be other parts such as a resistor device, a capacitor device, and a printed circuit as long as the parts can be soldered.

In the connection construction 100, the IGBT device 10 and the ceramic substrate 20 are bonded with the solder layer 30 mechanically, electrically and thermally. The heat generated in the IGBT device 10 is radiated from the ceramic substrate 20 through the solder layer 30.

The connection construction 100 is manufactured as follows. A solder pellet is sandwiched between the IGBT device 10 and the ceramic substrate 20, and then, they are decompressed at a temperature equal to or lower than a solidus of the solder layer 30. Successively, they are heated up to a temperature equal to or higher than a liquidus of the solder layer 30 under a decompressed state. Then, they are pressurized up to a pressure higher than the decompressed state at the temperature equal to or higher than the liquidus of the solder layer 30. After that, they are cooled so that the melted solder pellet is solidified to be the solder layer 30.

Here, the decompressed pressure under the temperature equal to or lower than the solidus of the solder layer 30 is equal to or lower than 5×10⁴ Pa. Further, the pressure higher than the decompressed state at the temperature equal to or higher than the liquidus of the solder layer 30 is equal to an atmospheric pressure.

Preferably, the decompressed pressure under the temperature equal to or lower than the solidus of the solder layer 30 is equal to or lower than 1×10⁴ Pa. Furthermore, preferably, the decompressed pressure under the temperature equal to or lower than the solidus of the solder layer 30 is equal to or lower than 6×10³ Pa.

Further, it is preferred that the solder pellet is preliminarily heated up to a temperature equal to or lower than the solidus of the solder layer 30 at the atmospheric pressure before they are decompressed at the temperature equal to or lower than the solidus of the solder layer 30.

Next, a function of the connection construction 100 is described as follows.

The dimensions of the IGBT device 10 are 13 mm square, and the dimensions of the ceramic substrate 20 are 20 mm×40 mm. The dimensions of the solder pellet are 8 mm square and 0.25 mm thick. The solder pellet is a square plate. FIG. 2 shows the IGBT device 10 and the ceramic substrate 20 laminated through the solder pellet. FIG. 3 shows a void generation rate in the solder layer 30, which is determined as a void area ratio. Specifically, the void generation rate as the void area ratio is obtained by analyzing a X-ray transmission photograph. The photograph is taken from upper view of the connection construction 100, and then, the photograph is processed by an image processing method. Thus, the void area ratio is obtained. The void area ratio is defined by a ratio of areas between the solder layer expanded between the IGBT device 10 and the substrate 20 and the void. The void area ratio is required, for example, to be equal to or smaller than 2%, which is a required design value (i.e., a target void area ratio).

In FIG. 3, a point shown as IIIA represents the construction 100 having the Pb-free solder layer formed such that the solder pellet is decompressed before melting. A point shown as IIIB represents the construction 100 having the Pb-free solder layer formed such that the solder pellet is decompressed after melting. A point shown as IIIC represents the construction 100 having the Pb-free solder layer formed by the conventional method. A point shown as IIID represents the construction 100 having the Pb-Sn solder layer formed by the conventional method. Here, the point IIIA shows the construction manufactured by the method according to the preferred embodiment of the present invention. The point IIIA shows the construction manufactured by the method according to the preferred embodiment of the present invention. The other tree points IIIB-IIID show the construction as a comparison of this embodiment.

In the point IIID, the construction 100 is manufactured in such a manner that the Pb-Sn solder layer made of, for example, 10 wt. % of Sn and remaining percent of Pb is formed by soldering in the continuous hydrogen reduction furnace under the atmospheric pressure (i.e., 1×10⁵ Pa in FIG. 3). In this case, by optimizing the shape of the solder pellet and a reflow profile of the solder pellet, the void area ratio equal to or smaller than 2 wt. % is achieved. Specifically, the surface area of the solder pellet having the plate shape becomes smaller so that the void is limited from generating in the solder layer. Further, the melting process time becomes longer so that the void generated in the solder layer is removed appropriately. Here, the void area ratio shown as the point IIID in FIG. 3 is the most excellent case where the connection construction manufactured by the conventional method with using the Pb solder layer processed under atmospheric pressure.

In the point IIIC, the construction 100 is manufactured in such a manner that the Pb-free solder layer made of, for example, 5 wt. % of Sb and remaining percent of Sn is formed by soldering in the continuous hydrogen reduction furnace under the atmospheric pressure (i.e., 1×10⁵ Pa in FIG. 3). In this case, even though the shape of the solder pellet and a reflow profile of the solder pellet are optimized, the void area ratio equal to or smaller than 2 wt. % is not achieved. This is because the Pb-free solder has high surface tension so that the solder does not expand to the connection member sufficiently.

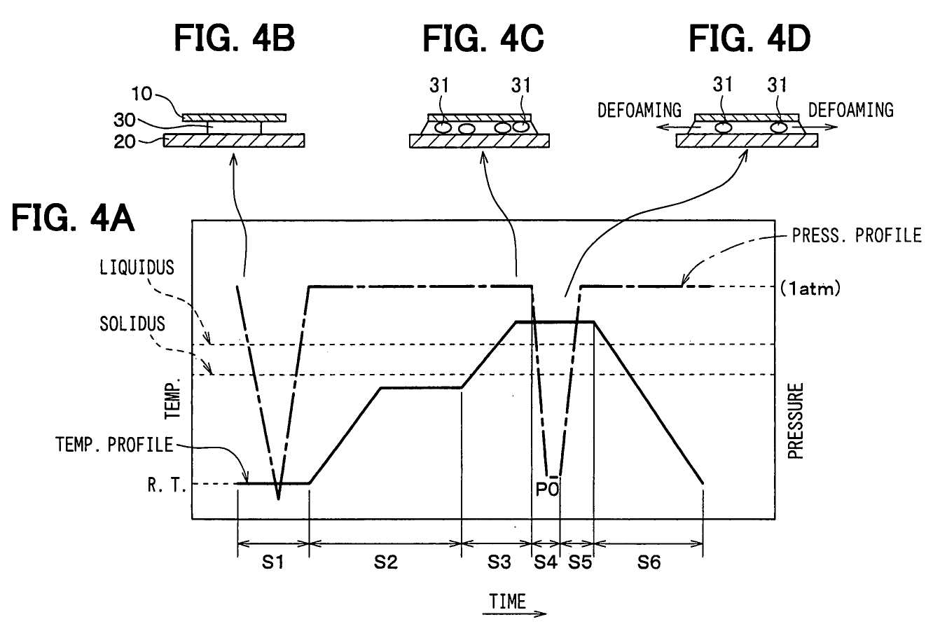

In the point IIIB, the construction 100 is manufactured in such a manner that the Pb-free solder layer is formed by reflowing under a decompressed pressure. Specifically, the void in the Pb-free solder is removed from the solder layer under the decompressed pressure. In this case, the Pb-free solder pellet is melted, and then, the melted pellet is decompressed. This method for removing the void is defined as a comparison decompressed defoaming method. In this comparison decompressed defoaming method, the Pb-free solder layer made of, for example, 5 wt. % of Sb and remaining percent of Sn is formed by soldering in a process shown in FIGS. 4A to 4D. FIG. 4A shows a temperature profile and a pressure profile of the soldering process in the comparison decompressed defoaming method. Steps S1-S6 in FIG. 4A are performed in this order. This soldering process can be performed by soldering equipment having a vacuum chamber capable of reflowing and decompressing. FIG. 4B shows the construction in Step S1, FIG. 4C shows the construction in Step S3, and FIG. 4D shows the construction in Step S5.

In Step S1, the solder pellet to form the solder layer 30 is sandwiched between the IGBT device 10 and the ceramic substrate 20, and then, they are mounted in the vacuum chamber. The vacuum chamber is evacuated from the atmospheric pressure (i.e., 1 atm) to a predetermined decompressed pressure at the room temperature (i.e., R.T.). Then, only nitrogen gas, only hydrogen gas or mixed gas of the nitrogen gas and the hydrogen gas is introduced into the vacuum chamber to be equal to the atmospheric pressure. Thus, the atmosphere in the vacuum chamber is exchanged to a solder gas.

In Step S2, the atmospheric pressure in the chamber is maintained, and the temperature of the solder pellet is increased from the room temperature to a predetermined temperature lower than the solidus of the solder layer 30. Thus, the preliminarily heating of the solder pellet is performed in Step S2. Here, the temperature of the solidus is about 235° C., and the temperature of the liquidus is about 240° C. in a case where the solder pellet is made of 5 wt. % of Sb and remaining percent of Sn. These temperatures of the solidus and the liquidus of the solder layer 30 can be obtained easily on the basis of phase equilibrium diagram of the solder composing the solder pellet (i.e., the solder layer 30).

The predetermined temperature lower than the solidus of the solder layer 30 as a preliminarily heating temperature is, for example, 200° C. This preliminarily heating provides that the solder pellet, the IGBT device 10 and the substrate 20 are heated to clean the surfaces thererof.

In Step S3, the atmospheric pressure is maintained, and the connection construction 100 is heated from the preliminarily heating temperature to a temperature higher than the liquidus of the solder composing the solder layer 30. Thus, a main heating process is performed with a main heating temperature. The main heating temperature is, for example, 280° C. This main heating process provides to melt the solder pellet so that the melted solder pellet expands to a predetermined area. In this case, the melted solder pellet may suck the atmospheric gas disposed around the melted solder pellet. Therefore, a void 31 may be formed in the melted solder pellet shown in FIG. 4C. The void 31 has an inner pressure inside the void 31, which is equal to the atmospheric pressure.

In Step S4, the main heating temperature is maintained to expand the melted solder pellet to a predetermined area, and then, the construction is evacuated from the atmospheric pressure to a predetermined pressure. Thus, the construction becomes in a decompressed state. This decompressed pressure is defined as P0. During this Step S4, the void 31 is removed from the melted solder pellet so that the void defoaming process is performed.

In Step S5, the main heating temperature is maintained, and the construction is pressurized from the decompressed pressure P0 to a predetermined pressure by introducing the soldering gas into the chamber. The predetermined pressure is higher than the decompressed pressure, and, in FIG. 4A, the predetermined pressure is equal to the atmospheric pressure.

In Step S6, the atmospheric pressure is maintained, and the melted solder pellet is cooled down to the room temperature so that the melted solder pellet is solidified. Thus, the solder layer 30 is formed, and the connection construction is completed. Here, all of the process of Step S1 to Step S6 takes about 15 minutes.

This comparison decompressed defoaming method provides that the void is effectively removed. The relationship between the void area ratio and the decompressed pressure P0 in Step S4 is shown as points IIIB in FIG. 3. When the decompressed pressure P0 is equal to or lower than 3000 Pa, the void area ratio becomes equal to or smaller than 2% so that the target void area ratio is achieved.

However, in view of variation of the void area ratio, it is required to set the decompressed pressure P0 to be equal to or lower than 100 Pa. Therefore, it takes much time to decompress from the atmospheric pressure to a predetermined pressure with controlling the temperature. Thus, the void area ratio depends on the process time for removing the void and the decompressed pressure P0. Therefore, to perform the comparison decompressed defoaming method for manufacturing the connection construction, an expensive vacuum system (i.e., decompressing means) is required, and it is also required to lengthen the process time for decompressing the chamber. Therefore, the manufacturing cost of the connection construction is increased.

In view of the above problem of the comparison decompressed defoaming method, the decompressed defoaming method for manufacturing the connection construction 100 according to the preferred embodiment of the present invention is shown as the points IIIA in FIG. 3.

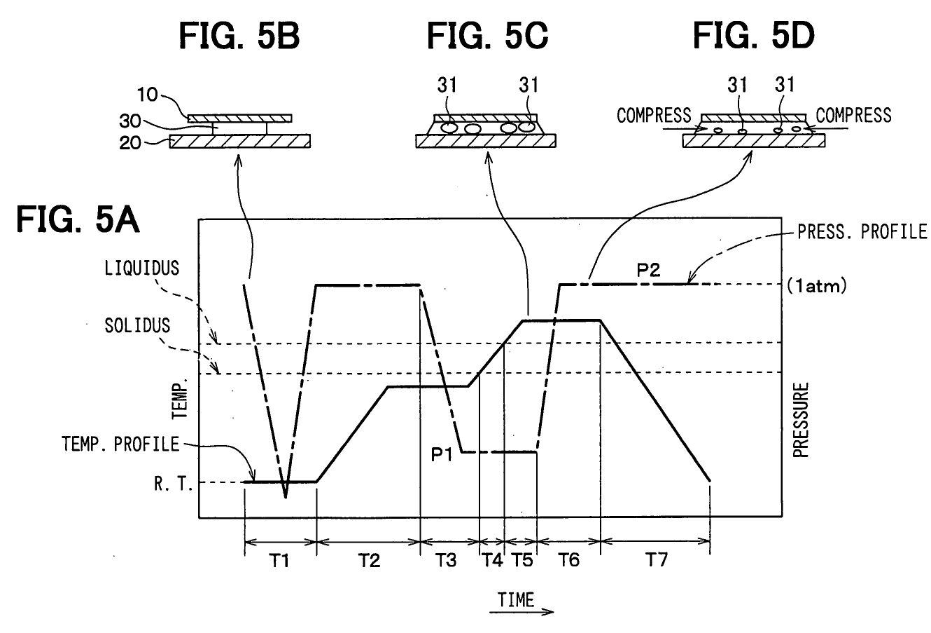

In the point IIIA, the construction 100 is manufactured in such a manner that the Pb-free solder layer made of, for example, 5 wt. % of Sb and remaining percent of Sn is formed by the following process shown in FIGS. 5A to 5D. In this case, the Pb-free solder pellet is melted after the pellet is decompressed. FIG. 5A shows a temperature profile and a pressure profile of the soldering process in the decompressed defoaming method. Steps T1-T7 in FIG. 5A are performed in this order. This soldering process can be performed by soldering equipment having a vacuum chamber capable of reflowing and decompressing. FIG. 5B shows the construction in Step T1, FIG. 5C shows the construction in Step T5, and FIG. 5D shows the construction in Step T6. The temperature profile in FIG. 5A shows that the solder pellet is preliminarily heated up to a predetermined temperature equal to or lower than the solidus of the solder composing the solder pellet (i.e., the solder layer 30). Then, the main heating process is performed at another predetermined temperature equal to or higher than the liquidus of the solder. The pressure profile in FIG. 5A shows an characteristics of the method.

In Step T1, the solder pellet to form the solder layer 30 is sandwiched between the IGBT device 10 and the ceramic substrate 20, and then, they are mounted in the vacuum chamber. The vacuum chamber is evacuated from the atmospheric pressure (i.e., 1 atm) to a predetermined decompressed pressure at the room temperature (i.e., R.T;). Then, only nitrogen gas, only hydrogen gas or mixed gas of the nitrogen gas and the hydrogen gas is introduced into the vacuum chamber to be equal to the atmospheric pressure. Thus, the atmosphere in the vacuum chamber is exchanged to a solder gas.

In Step T2, the atmospheric pressure in the chamber is maintained, and the temperature of the solder pellet is increased from the room temperature to a predetermined temperature lower than the solidus of the solder layer 30. Thus, the preliminarily heating of the solder pellet is performed in Step T2. Here, the temperature of the solidus is about 235° C., and the temperature of the liquidus is about 240° C. in a case where the solder pellet is made of 5 wt. % of Sb and remaining percent of Sn. These temperatures of the solidus and the liquidus of the solder layer 30 can be obtained easily on the basis of phase equilibrium diagram of the solder composing the solder pellet (i.e., the solder layer 30).

The predetermined temperature lower than the solidus of the solder layer 30 as a preliminarily heating temperature is, for example, 200° C. This preliminarily heating provides that the solder pellet, the IGBT device 10 and the substrate 20 are heated to clean the surfaces thererof.

In Step T3, the preliminarily heating temperature is maintained, and the connection construction 100 is decompressed from the atmospheric pressure to the first pressure P1.

In Step T4, the first pressure P1 is maintained, and the connection construction 100 is heated up to a predetermined temperature equal to the liquidus of the solder. In this case, the solder pellet is melted under the decompressed pressure P1.

In Step T5, the first pressure P1 is maintained, and the connection construction 100 is heated from the temperature near the luquidus to a predetermined main heating temperature higher than the liquidus of the solder. Thus, a main heating process is performed with the main heating temperature. The main heating temperature is, for example, 280° C.

During Steps T4 and T5, the solder pellet is melted so that the melted solder pellet expands to a predetermined area. In this case, the melted solder pellet may suck the atmospheric gas disposed around the melted solder pellet. Therefore, a void 31 may be formed in the melted solder pellet shown in FIG. 5C. The void 31 has an inner pressure inside the void 31, which is equal to the decompressed pressure P1.

In Step T6, the main heating temperature is maintained to expand the melted solder pellet to a predetermined area, and then, the construction is pressurized from the first pressure P1 to the second pressure P2 by introducing the soldering gas into the chamber. The second pressure P2 is higher than the first pressure P1. In FIG. 5, the second pressure P2 is equal to the atmospheric pressure.

In Step T7, the atmospheric pressure is maintained, and the melted solder pellet is cooled down to the room temperature so that the melted solder pellet is solidified. Thus, the solder layer 30 is formed, and the connection construction is completed. Here, all of the process of Step T1 to Step T6 takes about 15 minutes.

This decompressed defoaming method provides that the void is effectively removed. The relationship between the void area ratio and the first pressure P1 in Steps T4 and T5 is shown as points IIIA in FIG. 3. Even when the first pressure P1 as the decompressed pressure is comparatively high, the void 31 is reduced so that the void area ratio becomes smaller, compared with the case of the comparison decompressed defoaming method. Specifically, in a case of the comparison decompressed defoaming method, the target void area ratio (i.e., the ratio of 2%) is obtained when the decompressed pressure P0 becomes smaller than 3000 Pa. However, in a case of the present decompressed defoaming method, the target void area ratio is obtained when the first pressure P1 becomes smaller than 50000 Pa. Further, the void area ratio of the present decompressed defoaming method in a case where the first pressure is 10000 Pa is almost equal to that shown as the point IIID in FIG. 3 in a case where the connection construction is utmost optimally manufactured by the conventional method with using the Pb solder layer processed under atmospheric pressure. Furthermore, even when the decompressed pressure P0 is set to be equal to or smaller than 100 Pa in the comparison decompressed defoaming method, the void area ratio is not reduced lower than 1%. However, when the first pressure P1 is set to be equal to or lower than 6000 Pa in the present decompressed defoaming method, the void area ratio lower than 1% is easily and stably obtained.

Thus, in the present decompressed defoaming method, the first connection member as the IGBT device 10 and the second connection member as the ceramic substrate 20 sandwich the solder pellet to be the solder layer 30, and then, the solder pellet is decompressed at a predetermined temperature lower than the solidus of the solder composing the solder pellet. Then, the decompressed pressure is maintained, and the solder pellet is heated up to a predetermined temperature higher than the liquidus of the solder. After that, the solder pellet is compressed to be a predetermined pressure higher than the decompressed pressure with maintaining the temperature higher than the luquisus. Then, the melted solder pellet is cooled so that the solder layer 30 is formed.

In this method, when the solder pellet is heated up to a predetermined temperature higher than the liquidus, that is Step T5, the solder pellet is melted and the atmosphere is decompressed. Therefore, even when the melted solder pellet involves the atmospheric gas so that the void 31 is formed, as shown in FIG. 5C, the void 31 has the decompressed first pressure P1. Next, in Step T6, the melted solder pellet is pressurized from the first pressure P1 to the second pressure P2, which is higher than the first pressure P1, at the temperature higher than the liqiudus. Thus, the void 31 is collapsed by the second pressure P2. This is because the inner pressure of the void 31 is the first pressure P1 before Step T6. In Step T6, the atmospheric pressure becomes the second pressure P2, which is higher than the first pressure P1, so that the void 31 is collapsed.

Thus, the void 31 becomes much smaller or is disappeared so that the void 31 in the melted solder pellet is reduced. Therefore, the void can be reduced appropriately even when the first pressure P1 is not set to be a comparatively lower pressure compared with the comparison decompressed defoaming method. Specifically, even when the first pressure P1 is set to be higher than the decompressed pressure P0, the void 31 is much reduced.

Thus, the present decompressed defoaming method does not require the vacuum system having high evacuation performance as decompressing means for decompressing the connection construction 100. Further, the decompressing process time for decompressing the construction 100 becomes shorter; and therefore, the void 31 in the solder layer 30 is effectively reduced with a low cost.

As described above, in the present decompressed defoaming method for manufacturing the connection construction 100, it is preferred that the first pressure P1 in the decompressed process in Steps T3 to T5 is equal to or lower than 5×10⁴ Pa. Further, it is preferred that the second pressure P2, which is higher than the first pressure P1, is equal to the atmospheric pressure, i.e., 1 atm. In these cases, the void 31 is effectively reduced. Specifically, when the second pressure P2 is equal to the atmospheric pressure, an additional compressor for pressurizing the construction 100 is not necessitated, so that the equipment for manufacturing the construction 100 can become simple. Thus, the manufacturing cost is reduced.

Further, in the present method, the first pressure P1 is set to be equal to or lower than 5×10⁴ Pa so that the void area ratio becomes lower than the target ratio. However, in the comparison decompressed defoaming method, to reduce the void area ratio lower than the target ratio, the decompressed pressure P0 is required to be equal to or lower than 3000 Pa, which is almost one figure lower than 5×10⁴ Pa.

Preferably, the first pressure P1 is set to be equal to or lower than 1×10⁴ Pa. In this case, the void area ratio shown as the point IIIA in FIG. 3 is almost equal to that shown as the point IIID in FIG. 3 in a case where the connection construction is utmost optimally manufactured by the conventional method with using the Pb solder layer processed under atmospheric pressure. This void ratio is the minimum ratio in the conventional method by optimizing the shape of the solder pellet and the temperature profile of the manufacturing process.

Further, preferably, the first pressure P1 in the present method is equal to or lower than 6×10³ Pa. In this case, the void area ratio shown as the point IIIA in FIG. 3 is almost a half of the ratio (i.e., 1%) shown as the point IIIB in FIG. 3 in a case where the connection construction is utmost optimally manufactured by the comparison method.

In this embodiment, before the construction 100 is decompressed to be the first pressure P1 at a predetermined temperature lower than the solidus, the solder pellet is preliminarily heated up to a predetermined temperature lower than the solidus under the atmospheric pressure, as shown in Step T2 in FIG. 5. In this case, the surface of the solder pellet is cleaned by the preliminarily heating. Therefore, the preliminarily heating is preferred for the manufacturing method. However, this preliminarily heating process can be skipped.

(Modifications)

Although the second pressure P2 is set to be equal to the atmospheric pressure, the second pressure P2 can be set to be another pressure, as long as the second pressure P2 is higher than the first pressure P1. For example, the second pressure P2 can be set to be higher than the atmospheric pressure. In this case, the first pressure P1 is set to be equal to that in the above described embodiment. Further, the first pressure P1 can be set in such a manner that the pressure difference between the first and the second pressures P1, P2 in a case where the second pressure P2 is higher than the atmospheric pressure is equal to or larger than that in a case where the second pressure P2 is equal to the atmospheric pressure.

Although the solder pellet does not include lead, the solder pellet can include lead. Further, the solder pellet can be made of another solder such as Pb-Sn solder.

Although the first connection member is the IGBT device 10, and the second connection member is the ceramic substrate 20, the first connection member can be a resistor device or a capacitor device, and the second connection member can be a printed circuit board. Further, the first and the second connection members can be other devices or substrates as long as they can be bonded with solder.

Such changes and modifications are to be understood as being within the scope of the present invention as defined by the appended claims.

1. A method for manufacturing a connection construction having a first and a second connection members bonded therebetween with a solder layer made of a solder, the method comprising the steps of:
sandwiching the solder layer between the first and the second connection members;
decompressing the first and the second connection members with the solder layer down to a first pressure with maintaining a first temperature, which is lower than a solidus of the solder;
heating the first and the second connection members with the solder layer up to a second temperature with maintaining the first pressure, the second temperature being higher than a liquidus of the solder;
compressing the first and the second connection members with the solder layer up to a second pressure with maintaining the second temperature, the second pressure being higher than the first pressure; and
solidifying the solder with maintaining the second pressure.

2. The method according to claim 1, wherein
the first pressure is equal to or lower than 5×10⁴ Pa, and
the second pressure is equal to an atmospheric pressure.

3. The method according to claim 2, wherein
the first pressure is equal to or lower than 1×10⁴ Pa.

4. The method according to claim 3, wherein
the first pressure is equal to or lower than 6×10³ Pa.

5. The method according to claim 1, further comprising the step of:
preliminarily heating the first and the second connection members with the solder layer up to a preliminarily heating temperature with maintaining an atmospheric pressure before the step of decompressing, the preliminarily heating temperature being equal to or lower than the solidus of the solder.

6. The method according to claim 1, wherein
the solder is made of lead free solder.
